(19) United States
(12) Patent Application Publication
(10) Pub. No.: US 2007/0128441 A1
(43) Pub. Date: Jun. 7, 2007

(54) Process for the production of strongly adherent coatings

(76) Inventors: Giorgio Macor, Sasso Marconi (BO) (IT); Rosanna Telesca, Sasso Marconi (IT); Eduardo Ruiz, Basel (CH); Stephan Ilg, Giebenach (CH)

Correspondence Address: CIBA SPECIALTY CHEMICALS CORPORATION;PATENT DEPARTMENT, 540 WHITE PLAINS RD, P O BOX 2005, TARRYTOWN, NY, 10591-9005, US

(21) Appl. No.: 10/566,741

(22) PCT Filed: Jul. 26, 2004
(86) PCT No.: PCT/EP04/51600

§ 371 Date: Jan. 31, 2006

(30) Foreign Application Priority Data
Aug. 4, 2003 (EP) 03102424.3

(51) Int. Cl. B32B 9/04; B05D 3/08; C23C 16/00; C08F 2/46; H05H 1/24

(52) U.S. Cl. 428/411.1; 427/532; 427/223; 427/487; 427/248.1; 427/569

(57) ABSTRACT

The invention relates to a process and to the corresponding apparatus for the production of strongly adherent coatings on an inorganic or organic substrate, wherein in a first step a) a low-temperature plasma, a corona discharge or a flame is caused to act on the inorganic or organic substrate, in a second step b) one or more photoinitiators or mixtures of photoinitiators with monomers, containing at least one ethylenically unsaturated group, or solutions, suspensions or emulsions of the afore-mentioned substances, are applied at normal pressure to the inorganic or organic substrate, in a third step c) using suitable methods those afore-mentioned substances are dried and/or irradiated with electromagnetic waves and, optionally, in a fourth step d) on the substrate so pretreated is deposited a metal, half-metal or metal oxide.

The invention relates to a process for the production of strongly adhering coatings of metal on inorganic or organic substrates, wherein a low-temperature plasma treatment, a corona discharge treatment or a flame treatment is carried out on the inorganic or organic substrate, one or more photoinitiators are applied at normal pressure to the inorganic or organic substrate, and the substrate so precoated with photoinitiator is coated with a metal. The invention relates also to the use of photoinitiators in the production of such layers and to the strongly adherent coatings themselves.

The adhesion properties of coatings (e.g. finishes, paints, printing inks or adhesives) on inorganic or organic substrates, especially on non-polar substrates such as polyethylene, polypropylene or fluorine-containing polyolefins, are frequently inadequate. For that reason additional treatments have to be carried out in order to achieve satisfactory results. The adhesion can be improved by first applying special priming coatings, so-called primers, and only then applying the desired coating thereto.

A further possibility lies in exposing the substrates to be coated to a plasma treatment or corona treatment and then coating them, it being possible for a grafting process with e.g. acrylate monomers to be carried out between those two operations (J. Polym. Sci., Part A: Polym. Chem. 31, 1307-1314 (1993)).

The production of low-temperature plasmas and the plasma-assisted deposition of thin organic or inorganic layers, both under vacuum conditions and under normal pressure, have been known for some time. Fundamental principles and applications are described, for example, by A. T. Bell, “Fundamentals of Plasma Chemistry” in “Technology and Application of Plasma Chemistry”, edited by J. R. Holahan and A. T. Bell, Wiley, N.Y. (1974) and H. Suhr, Plasma Chem. Plasma Process 3(1),1, (1983).

It is also possible in plasmas to carry out polymerisations that result in the deposition of polymeric layers and can be used as primers. Fundamental principles and applications are described, for example, by H. Biederman, Y. Osada “Plasma Polymerization Processes” in “Plasma technology 3” edited by L. Holland, Elsevier, Amsterdam 1992.

It is also known that plastics surfaces can be subjected to a plasma treatment and as a result the subsequently applied finish exhibits improved adhesion to the plastics substrate. This is described by H. J. Jacobasch et al. in Farbe+Lack 99(7), 602-607 (1993) for low-temperature plasmas under vacuum conditions and by J. Friedrich et al. in Surf. Coat. Technol. 59, 371-6 (1993) for plasmas ranging from in vacuo up to normal pressure conditions, the low-temperature plasma changing into a corona discharge.

A process similar to the kind mentioned at the beginning is known from WO 00/24527. That process describes the plasma treatment of substrates with immediate vapour-deposition and grafting-on of photoinitiators in vacuo. A disadvantage, however, is that vapour-deposition requires the use of vacuum apparatus and, because of low deposition rates, is not very efficient and is not suitable for industrial applications having high throughput rates. A similar process is disclosed in PCT-Application No. EP03/00780.

There is a need in the art for processes for the pretreatment of substrates that can readily be carried out in practice and are not too expensive in terms of apparatus by means of which the subsequent coating of those substrates is improved.

It has now been found that coatings of metal, metal oxide or half-metal having especially good adhesion can be obtained by applying a photoinitiator to a substrate to be coated, after that substrate has been subjected to a plasma treatment (low pressure and/or normal pressure plasmas), corona treatment or flame treatment, optionally drying, and irradiating the substrate so treated. The substrates so pretreated are provided with a metal, half-metal or metal oxide coating. The resulting coatings exhibit surprisingly good adhesion.

The invention therefore relates to a process for the production of a strongly adherent metal coating on an inorganic or organic substrate, wherein

a) a low temperature plasma treatment, a corona discharge treatment or a flame treatment is carried out on the inorganic or organic substrate,

b) one or more photoinitiators or mixtures of photoinitiators with monomers or/and oligomers, containing at least one ethylenically unsaturated group, or solutions, suspensions or emulsions of the afore-mentioned substances, are applied to the inorganic or organic substrate,

c) the layer of step b) is optionally dried and is irradiated with electromagnetic waves; and

d) on the substrate so precoated with photoinitiator a metal, half-metal or metal oxide is deposited from the gasphase.

Preferably in step d) an irradiation with electromagnetic waves is carried out, either while depositing the metal, half-metal or metal oxide from the gasphase or after the deposition.

The process is simple to carry out and allows a high throughput per unit of time.

In the process according to the invention, after the photoiniator or photoinitiators, or a solution or dispersion thereof in a solvent or monomer, has or have been applied to the substrate which has been plasma-, corona- or flame-pretreated and after any drying step for evaporating off any solvent used, a fixing step for the photoinitiator is carried out by exposure to UV/VIS light. In the context of the present Application, the term “drying” includes both variants, both the removal of the solvent and the fixing of the photoinitiator.

In step c) of the above-described preferred process, the drying, that is to say the removal of the solvent, is optional. That step can be omitted, for example, when no solvent was used. The fixing of the photoinitiator in step c) by irradiation with electromagnetic waves, especially UV/VIS radiation, must be carried out.

Process step b) in the above-described process is preferably carried out under normal pressure.

If, in process step b), mixtures of photoinitiators with monomers or/and oligomers are used, the use of mixtures of one or more photoinitiators with monomers is preferred.

Possible ways of obtaining plasmas under vacuum conditions have been described frequently in the literature. The electrical energy can be coupled in by inductive or capacitive means. It may be direct current or alternating current; the frequency of the alternating current may range from a few kHz up into the MHz range. A power supply in the microwave range (GHz) is also possible.

The principles of plasma production and maintenance are described, for example, in the review articles by A. T. Bell and H. Suhr mentioned above.

As primary plasma gases it is possible to use, for example, He, argon, xenon, N₂, O₂, H₂, steam or air.

The process according to the invention is not sensitive per se in respect of the coupling-in of the electrical energy.

The process can be carried out batchwise, for example in a rotating drum, or continuously in the case of films, fibres or woven fabrics. Such methods are known and are described in the prior art.

The process can also be carried out under corona discharge conditions. Corona discharges are produced under normal pressure conditions, the ionised gas used being most frequently air. In principle, however, other gases and mixtures are also possible, as described, for example, in COATING Vol. 2001, No. 12, 426, (2001). The advantage of air as ionisation gas in corona discharges is that the operation can be carried out in an apparatus open to the outside and, for example, a film can be drawn through continuously between the discharge electrodes. Such process arrangements are known and are described, for example, in J. Adhesion Sci. Technol. Vol 7, No. 10, 1105, (1993). Three-dimensional workpieces can be treated with a plasma jet, the contours being followed with the assistance of robots.

The flame treatment of substrates is known to the person skilled in the art. Corresponding industrial apparatus, for example for the flame treatment of films, is commercially available. In such a treatment, a film is conveyed on a cooled cylindrical roller past the flame-treatment apparatus, which consists of a chain of burners arranged in parallel, usually along the entire length of the cylindrical roller. Details can be found in the brochures of the manufacturers of flame-treatment apparatus (e.g. esse Cl, flame treaters, Italy). The parameters to be chosen are governed by the particular substrate to be treated. For example, the flame temperatures, the flame intensity, the dwell times, the distance between substrate and burner, the nature of the combustion gas, air pressure, humidity, are matched to the substrate in question. As flame gases it is possible to use, for example, methane, propane, butane or a mixture of 70% butane and 30% propane.

The inorganic or organic substrate to be treated can be in any solid form. The substrate is preferably in the form of a woven fabric, a fibre, a film or a three-dimensional workpiece. The substrate may be, for example, a thermoplastic, elastomeric, inherently crosslinked or crosslinked polymer, another metal oxide (than e.g. the one to be deposited), a ceramic material, glass, another metal (than e.g. the one to be deposited), leather or textile.

The pretreatment of the substrate in the form of plasma-, corona- or flame-treatment can be carried out, for example, immediately after the extrusion of a fibre or film, and also directly after film-drawing.

The inorganic or organic substrate is preferably a thermoplastic, elastomeric, inherently crosslinked or crosslinked polymer, a ceramic material or a glass, especially a thermoplastic, elastomeric, inherently crosslinked or crosslinked polymer.

Examples of thermoplastic, elastomeric, inherently crosslinked or crosslinked polymers are listed below.

1. Polymers of mono- and di-olefins, for example polypropylene, polyisobutylene, polybutene-1, poly-4-methylpentene-1, polyisoprene or polybutadiene and also polymerisates of cyclo-olefins, for example of cyclopentene or norbornene; and also polyethylene (which may optionally be crosslinked), for example high density polyethylene (HDPE), high density polyethylene of high molecular weight (HDPE-HMW), high density polyethylene of ultra-high molecular weight (HDPE-UHMW), medium density polyethylene (MDPE), low density polyethylene (LDPE), and linear low density polyethylene (LLDPE), (VLDPE) and (ULDPE). Polyolefins, that is to say polymers of mono-olefins, as mentioned by way of example in the preceding paragraph, especially polyethylene and polypropylene, can be prepared by various processes, especially by the following methods:
a) by free radical polymerisation (usually at high pressure and high temperature);
b) by means of a catalyst, the catalyst usually containing one or more metals of group IVb, Vb, VIb or VIII. Those metals generally have one or more ligands, such as oxides, halides, alcoholates, esters, ethers, amines, alkyls, alkenyls and/or aryls, which may be either π- or σ-coordinated. Such metal complexes may be free or fixed to carriers, for example to activated magnesium chloride, titanium (III) chloride, aluminium oxide or silicon oxide. Such catalysts may be soluble or insoluble in the polymerisation medium. The catalysts can be active as such in the polymerisation or further activators may be used, for example metal alkyls, metal hydrides, metal alkyl halides, metal alkyl oxides or metal alkyl oxanes, the metals being elements of group(s) Ia, IIa and/or IIIa. The activators may have been modified, for example, with further ester, ether, amine or silyl ether groups. Such catalyst systems are usually referred to as Phillips, Standard Oil Indiana, Ziegler (-Natta), TNZ (DuPont), metallocene or Single Site Catalysts (SSC).

2. Mixtures of the polymers mentioned under 1), for example mixtures of polypropylene with polyisobutylene, polypropylene with polyethylene (for example PP/HDPE, PP/LDPE) and mixtures of different types of polyethylene (for example LDPE/HDPE).

3. Copolymers of mono- and di-olefins with one another or with other vinyl monomers, for example ethylene/propylene copolymers, linear low density polyethylene (LLDPE) and mixtures thereof with low density polyethylene (LDPE), propylene/butene-1 copolymers, propylene/isobutylene copolymers, ethylene/butene-1 copolymers, ethylene/hexene copolymers, ethylene/methylpentene copolymers, ethylene/heptene copolymers, ethylene/octene copolymers, propylene/butadiene copolymers, isobutylene/isoprene copolymers, ethylene/alkyl acrylate copolymers, ethylene/alkyl methacrylate copolymers, ethylene/vinyl acetate copolymers and copolymers thereof with carbon monoxide, or ethylene/acrylic acid copolymers and salts thereof (ionomers), and also terpolymers of ethylene with propylene and a diene, such as hexadiene, dicyclopentadiene or ethylidenenorbornene; and also mixtures of such copolymers with one another or with polymers mentioned under 1), for example polypropylene-ethylene/propylene copolymers, LDPE-ethylene/vinyl acetate copolymers, LDPE-ethylene/acrylic acid copolymers, LLDPE-ethylene/vinyl acetate copolymers, LLDPE-ethylene/acrylic acid copolymers and alternately or randomly structured polyalkylene-carbon monoxide copolymers and mixtures thereof with other polymers, for example polyamides.

4. Hydrocarbon resins (for example C₅-C₉) including hydrogenated modifications thereof (for example tackifier resins) and mixtures of polyalkylenes and starch.

5. Polystyrene, poly(ρ-methylstyrene), poly(α-methylstyrene).

6. Copolymers of styrene or α-methylstyrene with dienes or acrylic derivatives, for example styrene/butadiene, styrene/acrylonitrile, styrene/alkyl methacrylate, styrene/butadiene/alkyl acrylate and methacrylate, styrene/maleic anhydride, styrene/acrylonitrile/methyl acrylate; high-impact-strength mixtures consisting of styrene copolymers and another polymer, for example a polyacrylate, a diene polymer or an ethylene/propylene/diene terpolymer; and also block copolymers of styrene, for example styrene/butadiene/styrene, styrene/isoprene/styrene, styrene/ethylene-butylene/styrene or styrene/ethylene-propylene/-styrene.

7. Graft copolymers of styrene or α-methylstyrene, for example styrene on polybutadiene, styrene on polybutadiene/styrene or polybutadiene/acrylonitrile copolymers, styrene and acrylonitrile (or methacrylonitrile) on polybutadiene; styrene, acrylonitrile and methyl methacrylate on polybutadiene; styrene and maleic anhydride on polybutadiene; styrene, acrylonitrile and maleic anhydride or maleic acid imide on polybutadiene; styrene and maleic acid imide on polybutadiene, styrene and alkyl acrylates or alkyl methacrylates on polybutadiene, styrene and acrylonitrile on ethylene/propylene/diene terpolymers, styrene and acrylonitrile on polyalkyl acrylates or polyalkyl methacrylates, styrene and acrylonitrile on acrylate/butadiene copolymers, and mixtures thereof with the copolymers mentioned under 6), such as those known, for example, as so-called ABS, MBS, ASA or AES polymers.

8. Halogen-containing polymers, for example polychloroprene, chlorinated rubber, chlorinated and brominated copolymer of isobutylene/isoprene (halobutyl rubber), chlorinated or chlorosulfonated polyethylene, copolymers of ethylene and chlorinated ethylene, epichlorohydrin homo- and co-polymers, especially polymers of halogen-containing vinyl compounds, for example polyvinyl chloride, polyvinylidene chloride, polyvinyl fluoride, polyvinylidene fluoride; and copolymers thereof, such as vinyl chloride/vinylidene chloride, vinyl chloride/vinyl acetate or vinylidene chloride/vinyl acetate.

9. Polymers derived from α,β-unsaturated acids and derivatives thereof, such as polyacrylates and polymethacrylates, or polymethyl methacrylates, polyacrylamides and polyacrylonitriles impact-resistant-modified with butyl acrylate.

10. Copolymers of the monomers mentioned under 9) with one another or with other unsaturated monomers, for example acrylonitrile/butadiene copolymers, acrylonitrile/alkyl acrylate copolymers, acrylonitrile/alkoxyalkyl acrylate copolymers, acrylonitrile/vinyl halide copolymers or acrylonitrile/alkyl methacrylate/butadiene terpolymers.

11. Polymers derived from unsaturated alcohols and amines or their acyl derivatives or acetals, such as polyvinyl alcohol, polyvinyl acetate, stearate, benzoate or maleate, polyvinylbutyral, polyallyl phthalate, polyallylmelamine; and the copolymers thereof with olefins mentioned in Point 1.

12. Homo- and co-polymers of cyclic ethers, such as polyalkylene glycols, polyethylene oxide, polypropylene oxide or copolymers thereof with bisglycidyl ethers.

13. Polyacetals, such as polyoxymethylene, and also those polyoxymethylenes which contain comonomers, for example ethylene oxide; polyacetals modified with thermoplastic polyurethanes, acrylates or MBS.

14. Polyphenylene oxides and sulfides and mixtures thereof with styrene polymers or polyamides.

15. Polyurethanes derived from polyethers, polyesters and polybutadienes having terminal hydroxyl groups on the one hand and aliphatic or aromatic polyisocyanates on the other hand, and their initial products.

16. Polyamides and copolyamides derived from diamines and dicarboxylic adds and/or from aminocarboxylic acids or the corresponding lactams, such as polyamide 4, polyamide 6, polyamide 6/6, 6/10, 6/9, 6/12, 4/6, 12/12, polyamide 11, polyamide 12, aromatic polyamides derived from m-xylene, diamine and adipic acid; polyamides prepared from hexamethylenediamine and iso- and/or tere-phthalic acid and optionally an elastomer as modifier, for example poly-2,4,4-trimethylhexamethylene terephthalamide or poly-m-phenylene isophthalamide. Block copolymers of the above-mentioned polyamides with polyolefins, olefin copolymers, ionomers or chemically bonded or grafted elastomers; or with polyethers, for example with polyethylene glycol, polypropylene glycol or polytetramethylene glycol. Also polyamides or copolyamides modified with EPDM or ABS; and polyamides condensed during processing (“RIM polyamide systems”).

17. Polyureas, polyimides, polyamide imides, polyether imides, polyester imides, polyhydantoins and polybenzimidazoles.

18. Polyesters derived from dicarboxylic acids and dialcohols and/or from hydroxy-carboxylic acids or the corresponding lactones, such as polyethylene terephthalate, polybutylene terephthalate, poly-1,4-dimethylolcyclohexane terephthalate, polyhydroxybenzoates, and also block polyether esters derived from polyethers with hydroxyl terminal groups; and also polyesters modified with polycarbonates or MBS.

19. Polycarbonates and polyester carbonates.

20. Polysulfones, polyether sulfones and polyether ketones.

21. Crosslinked polymers derived from aldehydes on the one hand and phenols, urea or melamine on the other hand, such as phenol-formaldehyde, urea-formaldehyde and melamine-formaldehyde resins.

22. Drying and non-drying alkyd resins.

23. Unsaturated polyester resins derived from copolyesters of saturated and unsaturated dicarboxylic acids with polyhydric alcohols, and also vinyl compounds as crosslinking agents, and also the halogen-containing, difficultly combustible modifications thereof.

24. Crosslinkable acrylic resins derived from substituted acrylic esters, e.g. from epoxy acrylates, urethane acrylates or polyester acrylates.

25. Alkyd resins, polyester resins and acrylate resins that are crosslinked with melamine resins, urea resins, isocyanates, isocyanurates, polyisocyanates or epoxy resins.

26. Crosslinked epoxy resins derived from aliphatic, cycloaliphatic, heterocyclic or aromatic glycidyl compounds, e.g. products of bisphenol-A diglycidyl ethers, bisphenol-F diglycidyl ethers, that are crosslinked using customary hardeners, e.g. anhydrides or amines with or without accelerators.

27. Natural polymers, such as cellulose, natural rubber, gelatin, or polymer-homologously chemically modified derivatives thereof, such as cellulose acetates, propionates and butyrates, and the cellulose ethers, such as methyl cellulose; and also colophonium resins and derivatives.

28. Mixtures (polyblends) of the afore-mentioned polymers, for example PP/EPDM, polyamide/EPDM or ABS, PVC/EVA, PVC/ABS, PVC/MBS, PC/ABS, PBTP/ABS, PC/ASA, PC/PBT, PVC/CPE, PVC/acrylates, POM/thermoplastic PUR, PC/thermoplastic PUR, POM/acrylate, POM/MBS, PPO/HIPS, PPO/PA 6.6 and copolymers, PA/HDPE, PA/PP, PA/PPO, PBT/PC/ABS or PBT/PET/PC.

The substrate can for example be one as used in the commercial printing area, sheet-fat- or web-printing, posters, calendars, forms, labels, wrapping foils, tapes, credit cards, furniture profiles, etc.. The substrate is not restricted to the use in the non-food area. The substrate may also be, for example, a material for use in the field of nutrition, e.g. as packaging for foodstuffs; cosmetics, medicaments, etc..

Where substrates have been pretreated according to processes of the invention it is also possible, for example, for substrates that usually have poor compatibility with one another to be adhesively bonded to one another or laminated.

Within the context of the present invention, paper should also be understood as being an inherently crosslinked polymer, especially in the form of cardboard, which can additionally be coated with e.g. Teflon®. Such substrates are, for example, commercially available.

The thermoplastic, crosslinked or inherently crosslinked plastics is preferably a polyolefin, polyamide, polyacrylate, polycarbonate, polystyrene or an acrylic/melamine, alkyd or polyurethane surface-coating.

Polycarbonate, polyethylene and polypropylene are especially preferred.

The plastics may be, for example, in the form of films, injection-moulded articles, extruded workpieces, fibres, felts or woven fabrics.

As inorganic substrates there come into consideration especially glass, ceramic materials, metal oxides and metals. They may be silicates and semi-metal or metal oxide glasses which are preferably in the form of layers or in the form of powders preferably having average particle diameters of from 10 nm to 2000 μm. The particles may be dense or porous. Examples of oxides and silicates are SiO₂, TiO₂, Zro₂, MgO, NiO, WO₃, Al₂O₃, La₂O₃, silica gels, days and zeolites. Preferred inorganic substrates, in addition to metals, are silica gels, aluminium oxide, titanium oxide and glass and mixtures thereof.

As metal substrates there come into consideration especially Fe, Al, Ti, Ni, Mo, Cr and steel alloys.

Photoinitiators suitable for use in the process according to the invention are in principle any compounds and mixtures that form one or more free radicals when irradiated with electromagnetic waves. These include initiator systems consisting of a plurality of initiators and systems that function independently of one another or synergistically. In addition to coinitiators, for example amines, thiols, borates, enolates, phosphines, carboxylates and imidazoles, it is also possible to use sensitisers, for example acridines, xanthenes, thiazenes, coumarins, thioxanthones, triazines and dyes. A description of such compounds and initiator systems can be found e.g. in Crivello J. V., Dietliker K. K., (1999): Chemistry & Technology of UV & EB Formulation for Coatings, Inks & Paints, and in Bradley G. (ed.) Vol. 3: Photoinitiators for Free Radical and Cationic Polymerisation 2nd Edition, John Wiley & Son Ltd. The photoinitiator suitable for the process according to the invention in step b) may be either an initiator having an unsaturated group or an initiator not having such a group Such compounds and derivatives are derived, for example, from the following classes of compounds: benzoins, benzil ketals, acetophenones, hydroxyalkylphenones, aminoalkylphenones, acylphosphine oxides, acylphosphine sulfides, acyloxyiminoketones, alkylamino-substituted ketones, such as Michler's ketone, peroxy compounds, dinitrile compounds, halogenated acetophenones, phenylglyoxylates, dimeric phenylglyoxalates, benzophenones, oximes and oxime esters, thioxanthones, coumarins, ferrocenes, titanocenes, onium salts, sulfonium salts, iodonium salts, diazonium salts, borates, triazines, bisimidazoles, polysilanes and dyes. It is also possible to use combinations of the compounds from the mentioned classes of compounds with one another and combinations with corresponding coinitiator systems and/or sensitisers.

Examples of such photoinitiator compounds are α-hydroxycyclohexylphenyl-ketone or 2-hydroxy-2-methyl-1-phenyl-propanone, (4-methylthiobenzoyl)-1-methyl-1-morpholino-ethane, (4-morpholino-benzoyl)-1-benzyl-1-dimethylamino-propane, (4-morpholino-benzoyl)-1-(4-methylbenzyl)-1-dimethylamino-propane, (3,4-dimethoxy-benzoyl)1-benzyl-1-dimethyl-amino-propane, benzildimethylketal, (2,4,6-trimethylbenzoyl)-diphenyl-phosphinoxid, (2,4,6-trimethylbenzoyl)-ethoxy-phenyl-phosphinoxid, bis(2,6-dimethoxybenzoyl)-(2,4,4-trimethyl-pent-1-yl)phosphinoxid, bis(2,4,6-trimethylbenzoyl)-phenyl-phosphinoxid or bis(2,4,6-trimethylbenzoyl)-(2,4-dipentoxyphenyl)phosphinoxid, 5,5′-Oxodi(ethylenoxydicarbonylphenyl), 1-hydroxy-5-(Phenyldicarbonyloxy)-3-oxo-pentane and dicyclopentadienyl-bis(2,6-difluoro-3-pyrrolo)titan, bisacridine derivatives like 1,7-bis(9-acridinyl)heptane, oxime esters, for example 1-phenyl-1,2-propanedione-2-o-benzoyl)oxime, 1-phenyl-1,2-propanedione-2-(o-ethoxycarbonyl)oxime or other oxime esters as for example described in GB 2339571 and US2001/0012596; as well as benzophenone, 4-phenylbenzophenone, 4-phenyl-3′-methyl-benzophenone, 4-phenyl-2′,4′,6′-trimethylbenzophenone, 4-methoxybenzophenone, 4,4′-dimethoxybenzophenone, 4,4′-dimethylbenzophenone, 4,4′-dichlorobenzophenone, 4,4′- dimethylaminobenzophenone, 4,4′-diethylaminobenzophenone, 4-methylbenzophenone, 2,4,6-trimethylbenzophenone, 4-(4-methylthiophenyl)-benzophenone, 3,3′-dimethyl-4-methoxybenzophenone, methyl-2-benzoylbenzoat, 4-2-(hydroxyethylthio)benzophenone, 4-(4-tolylthio)benzophenon, 4-benzoyl-N,N,N-trimethylbenzolmethanaminiumchloride, 2-hydroxy-3-(4-benzoylphenoxy)-N,N,N-trimethyl-1-propanaminiumchloride monohydrate, 4-(13-acryloyl-1,4,7,10,13-pentaoxatridecyl)-benzophenone, 4-benzoyl-N,N-dimethyl-N-[2-(1-oxo-2-propenyl)oxy]ethyl-benzolmethanaminiumchloride; 2,2-dichloro-1-(4-phenoxyphenyl)-ethanone, 4,4′-bis(chloromethyl)-benzophenone, 4-methylbenzophenone, 2-methylbenzophenone, 3-methylbenzophenone, 4-chlorobenzophenone. 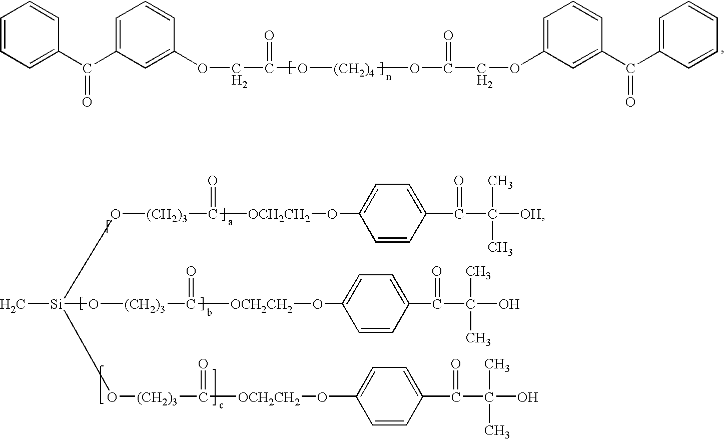
wherein a, b and c are an average value of 3 (SiMFPI2); as well as 2-chlorothioxanthone, 2,4-diethylthioxanthone, 2-isopropylthioxanthone, 3-isopropylthioxanthone, 1-chloro-4-propoxythioxanthone.

The photoinitiator is preferably a compound of formula I or Ia
(RG)—A—(IN) (I),
(IN)—A—(RG′)—A—(IN) (Ia),
wherein

(IN) is a photoinitiator base structure;

A is a spacer group or a single bond;

(RG) is hydrogen or at least one functional ethylenically unsaturated group; and

(RG′) is a single bond or a divalent radical that contains at least one functional ethylenically unsaturated group, or is a trivalent radical.

Of interest are compounds of formula I or Ia wherein

(IN) is a photoinitiator base structure of formula (II) or (III)

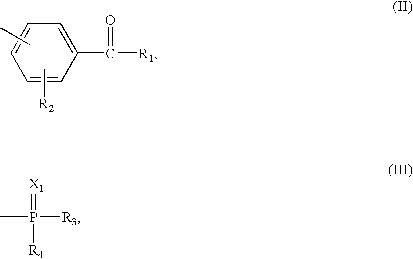

R₁ is a group (A), (B), (C) or (III)

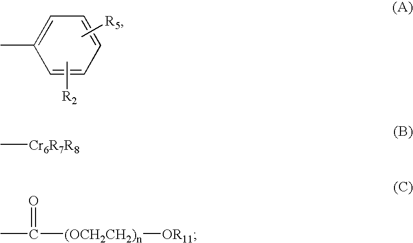

n is a number from 0 to 6;

R₂ is hydrogen, C₁-C₁₂alkyl, halogen, the group (RG)—A— or, when R₁ is a group (A), two radicals R₂ in the ortho-position to the carbonyl group may also together be —S— or 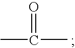
R₃ and R₄ are each independently of the other C₁-C₆alkyl, C₁-C₆alkanoyl, phenyl or benzoyl, the radicals phenyl and benzoyl each being unsubstituted or substituted by halogen, C₁-C₆alkyl, C₁-C₆alkylthio or by C₁-C₆alkoxy;

R₅ is hydrogen, halogen, C₁-C₁₂alkyl or C₁-C₁₂alkoxy or the group (RG)—A—;

R₆ is OR₉ or N(R₉)₂ or is 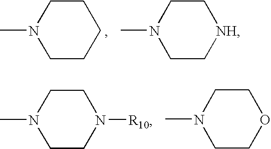
or SO₂R₉;

R₇ and R₈ are each independently of the other hydrogen, C₁-C₁₂alkyl, C₂-C₁₂alkenyl, C₁-C₁₂alkoxy, phenyl or benzyl or R₇ and R₈ together are C₂-C₆alkylene;

R₉ is hydrogen, C₁-C₆alkyl or C₁-C₆alkanoyl;

R₁₀ is hydrogen, C₁-C₁₂alkyl or phenyl;

R₁₁ is C₁C₄alkyl or 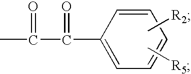
and

X₁ is oxygen or sulfur.

(IN) is, for example, a group

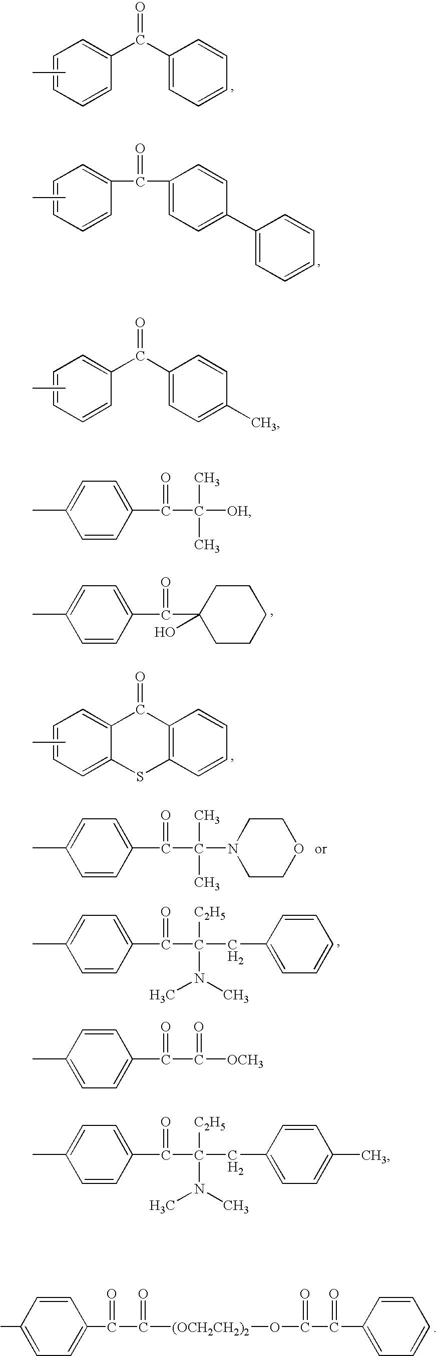

A in the compounds of formula I or Ia is, for example, a single bond, a spacer group

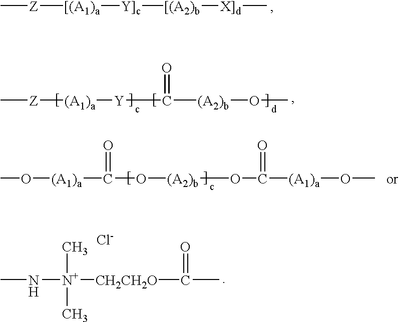

X, Y and Z are each independently of the others a single bond, —O—, —S—, —N(R₁₀)—, —(CO)—, —(CO)O—, —(CO)N(R₁₀), —O—(CO)—, —N(R₁₀)—(CO)— or —N(R₁₀)—(CO)O—.

A₁ and A₂ are e.g. each independently of the other C₁-C₄alkylene, C₃-C₁₂cycloalkylene, phenylene, phenylene-C₁-C₄alkylene or C₁-C₄alkylene-phenylene-C₁-C₄alkylene. a, b, c and d are each independently of the others a number from 0 to 4.

Special preference is given to compounds of formula I or Ia wherein A is a spacer group —Z—[(CH₂)ₐ—Y]_{c}—[(CH₂)_{b}—X]_{d}— and X, Y, Z, a, b, c and d are as defined above.

In the compounds of formula I or Ia

(RG) is hydrogen or R_{c}R_{b}C═CRₐ—, especially R_{c}R_{b}C═CRₐ—;

(RG′) is a single bond, 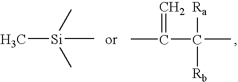
especially 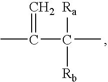
and

Rₐ, R_{b}, R_{c} are each H or C₁-C₆alkyl, especially H or CH₃.

The preparation of such photoinitiator compounds is known to the person skilled in the art and has already been described in a large number of publications.

For example, compounds containing unsaturated groups can be prepared by reaction of 4-[2-hydroxyethoxy)-benzoyl]-1-hydroxy-1-methyl-ethane (Irgacure® 2959, Ciba Spezialitätenchemie) with isocyanates containing acryloyl or methacryloyl groups or with other compounds containing acryloyl or methacryloyl groups, see e.g. U.S. Pat. No. 4,922,004. Commercially available unsaturated photoinitiators are, for example, 4-(13-acryloyl-1,4,7,10,13-pentaoxatridecyl)benzophenone (Uvecryl P36 from UCB), 4-benzoyl-N,N-dimethyl-N-[2-(1-oxo-2-propenyl)oxy]ethylphenylmethanaminium chloride (Quantacure ABQ from Great Lakes), and some copolymerisable unsaturated tertiary amines (Uvecryl P101, Uvecryl P104, Uvecryl P105, Uvecryl P115 from UCB Radcure Specialties) or copolymerisable aminoacrylates (Photomer 4116 and Photomer 4182 from Ackros; Laromer LR8812 from BASF; CN381 and CN386 from Cray Valley).

The publications indicated below provide further specific examples of suitable photoinitiator compounds having an ethylenically unsaturated function, and the preparation thereof: Unsaturated aceto- and benzo-phenone derivatives are described, for example, in U.S. Pat. No. 3,214,492, U.S. Pat. No. 3,429,852, U.S. Pat. No. 3,622,848 and U.S. Pat. No. 4,304,895, for example 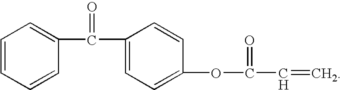
Also suitable, for example, are 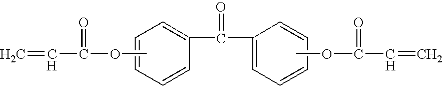
and further copolymerisable benzophenones, e.g. from UCB, Ebecryl P36 or in the form of Ebecryl P38 diluted in 30% tripropylene glycol diacrylate.

Copolymerisable, ethylenically unsaturated acetophenone compounds can be found, for example, in U.S. Pat. No. 4,922,004, for example 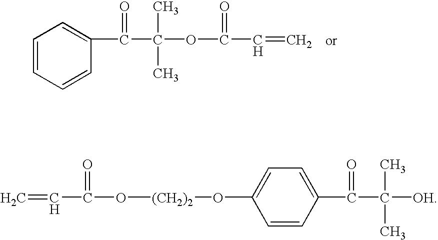
2-Acryloyl-thioxanthone has been published in Eur. Polym. J. 23, 985 (1987). Examples such as 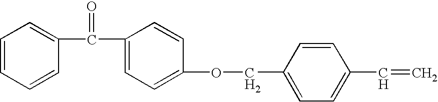
are described in DE 2 818 763. Further unsaturated carbonate-group-containing photo-initiator compounds can be found in EP 377 191. Uvecryl® P36 (already mentioned above), from UCB, is a benzophenone bonded to an acrylic function by ethylene oxide units (see Technical Bulletin 2480/885 (1985) from UCB or New. Polym. Mat. 1, 63 (1987)): 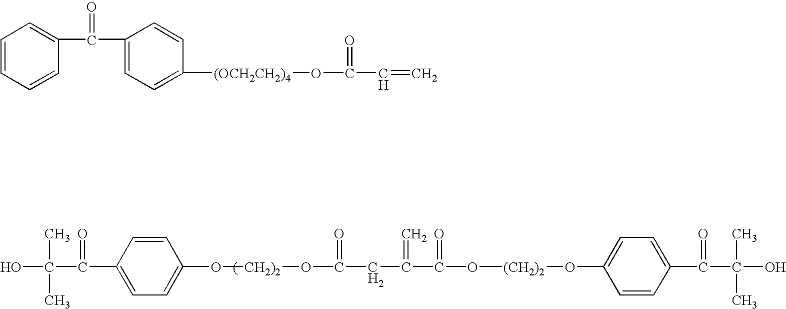
has been published in Chem. Abstr. 128: 283649r.

DE 195 01 025 gives further suitable ethylenically unsaturated photoinitiator compounds. Examples are 4-vinyloxycarbonyloxybenzophenone, 4-vinyloxycarbonyloxy-4′-chlorobenzophenone, 4-vinyloxycarbonyloxy-4′-methoxybenzophenone, N-vinyloxycarbonyl-4-amino-benzophenone, vinyloxycarbonyloxy-4′-fluorobenzophenone, 2-vinyloxycarbonyloxy4′-methoxybenzophenone, 2-vinyloxycarbonyloxy-5-fluoro-4′-chlorobenzophenone, 4-vinyloxycarbonyloxyacetophenone, 2-vinyloxycarbonyloxyacetophenone, N-vinyloxycarbonyl-4aminoacetophenone, 4-vinyloxycarbonyloxybenzil, 4-vinyloxycarbonyloxy-4′-methoxybenzil, vinyloxycarbonylbenzoin ether, 4-methoxybenzoinvinyloxycarbonyl ether, phenyl(2-vinyloxycarbonyloxy-2-propyl)-ketone, (4-isopropylphenyl)(2-vinyloxycarbonyloxy-2-propyl)-ketone, phenyl-(1-vinyloxycarbonyloxy)-cyclohexyl ketone, 2-vinyloxycarbonyloxy-9-fluorenone, 2-(N-vinyloxycarbonyl)-9-aminofluorenone, 2-vinylcarbonyloxymethylanthraquinone, 2-(N-vinyloxycarbonyl)aminoanthraquinone, 2-vinyloxycarbonyloxythioxanthone, 3-vinylcarbonyloxythioxanthone or

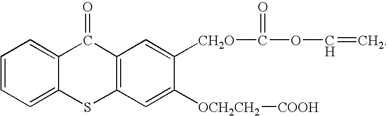

U.S. Pat. No. 4,672,079 discloses inter alia the preparation of 2-hydroxy-2-methyl(4-vinylpropiophenone), 2-hydroxy-2-methyl-p-(1-methylvinyl)propiophenone, p-vinylbenzoylcyclohexanol, p-(1-methylvinyl)benzoyl-cyclohexanol.

Also suitable are the reaction products, described in JP Kokai Hei 2-292307, of 4-[2-hydroxyethoxy)-benzoyl]-1-hydroxy-1-methyl-ethane (Irgacure® 2959, Ciba Spezialitätenchemie) and isocyanates containing acryloyl or methacryloyl groups, for example 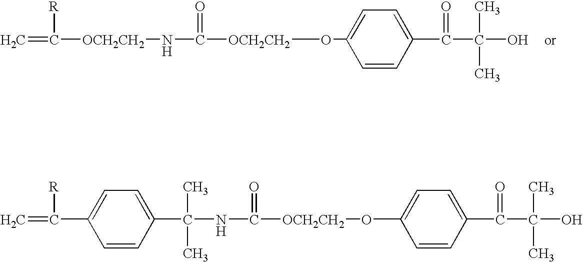
(wherein R═H or CH₃).

Further examples of suitable photoinitiators are

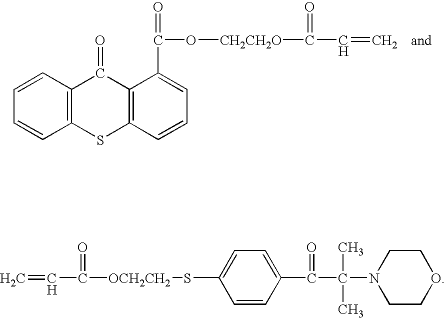

The following examples are described in Radcure '86, Conference Proceedings, 4-43 to 4-54 by W. Bäumer et al.

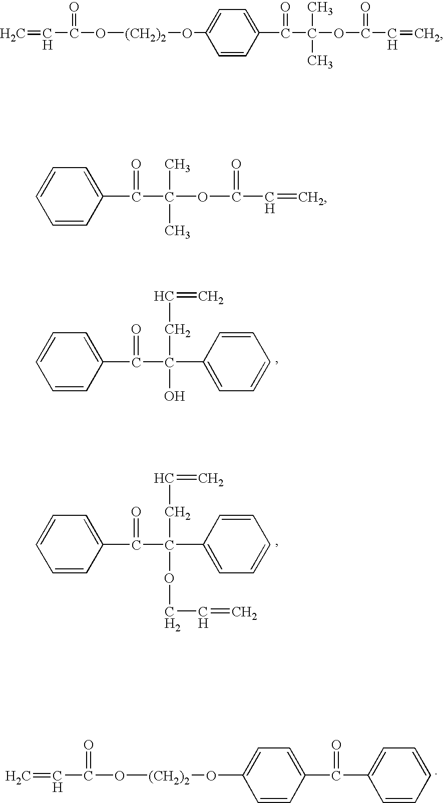

G. Wehner et al. report in Radtech '90 North America on 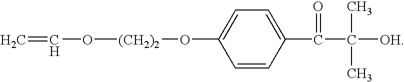
in the process according to the invention there are also suitable the compounds presented at RadTech 2002, North America 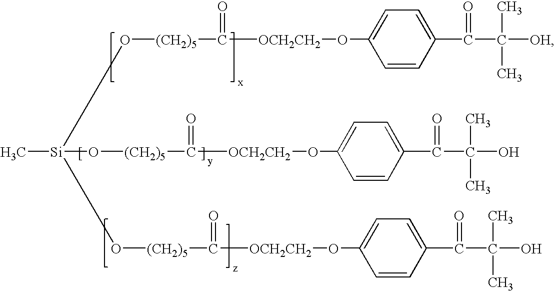
wherein x, y and z are an average of 3 (SiMFPI2) and 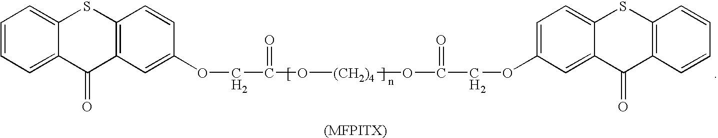
(MFPITX).

In the process according to the invention it is possible to use either saturated or unsaturated photoinitiators. It is preferable to use unsaturated photoinitiators.

In the process according to the invention it is of course also possible to employ mixtures of different photoinitiators, for example mixtures of saturated and unsaturated photoinitiators.

Photoinitiators without an unsaturated group are known to the person skilled in the art and a large number and variety of such photoinitiators are commercially available. In the process there are in principle suitable any photoinitiators that, after plasma-, corona- or flame-treatment, adhere to the surface of the substrate so treated.

The meanings of the substituents defined in formulae I and Ia in the different radicals are explained below.

C₁-C₁₂Alkyl is linear or branched and is, for example, C₁-C₈-, C₁-C₆- or C₁-C₄-alkyl. Examples are methyl, ethyl, propyl, isopropyl, n-butyl, sec-butyl, isobutyl, tert-butyl, pentyl, hexyl, heptyl, 2,4,4-trimethyl-pentyl, 2-ethylhexyl, octyl, nonyl, decyl, undecyl and dodecyl, especially e.g. methyl or butyl.

C₁-C₆Alkyl and C₁-C₄alkyl are likewise linear or branched and have e.g. the above-mentioned meanings up to the appropriate number of carbon atoms. C₁-C₆Alkyl substituents for benzoyl or phenyl are especially C₁-C₄alkyl, e.g. methyl or butyl.

Halogen is fluorine, chlorine, bromine and iodine, especially chlorine and bromine, preferably chlorine.

When R₁ is a group (A), and two radicals R₂ in the ortho-position to the carbonyl group together also are —S— or —C═O)—. there are obtained, for example, structures having a thioxanthone base structure 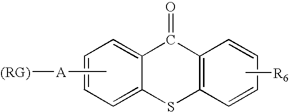
or anthraquinone base structure

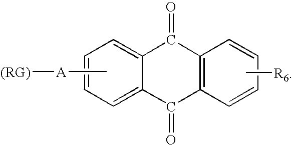

C₁-C₆Alkanoyl is linear or branched and is, for example, C₁-C₄alkanoyl. Examples are formyl, acetyl, propionyl, butanoyl, isobutanoyl, pentanoyl and hexanoyl, preferably acetyl. C₁-C₄Alkanoyl has the above-mentioned meanings up to the appropriate number of carbon atoms.

C₁-C₁₂Alkoxy denotes linear or branched radicals and is, for example, C₁-C₈-, C₁-C₆- or C₁-C₄-alkoxy. Examples are methoxy, ethoxy, propoxy, isopropoxy, n-butyloxy, sec-butyloxy, isobutyloxy, tert-butyloxy, pentyloxy, hexyloxy, heptyloxy, 2,4,4-trimethylpentyloxy, 2-ethyl-hexyloxy, octyloxy, nonyloxy, decyloxy and dodecyloxy, especially methoxy, ethoxy, propoxy, isopropoxy, n-butyloxy, sec-butyloxy, isobutyloxy, tert-butyloxy, preferably methoxy. C₁-C₈Alkoxy, C₁-C₆alkoxy and C₁-C₄alkoxy are likewise linear or branched and have e.g. the above-mentioned meanings up to the appropriate number of carbon atoms.

C₁-C₆Akylthio denotes linear or branched radicals and is, for example, C₁-C₄alkylthio. Examples are methylthio, ethylthio, propylthio, isopropylthio, n-butylthio, sec-butylthio, iso-butylthio, tert-butylthio, pentylthio and hexylthio, especially methylthio, ethylthio, propylthio, isopropylthio, n-butylthio, sec-butylthio, isobutylthio, tert-butylthio, preferably methylthio. C₁-C₄Alkylthio is likewise linear or branched and has e.g. the above-mentioned meanings up to the appropriate number of carbon atoms.

Phenyl or benzoyl radicals substituted by halogen, C₁-C₆alkyl, C₁-C₆alkylthio or by C₁-C₆alkoxy are e.g. mono- to penta-substituted, for example mono-, di- or tri-substituted, especially di- or tri-substituted, at the phenyl ring. Preference is given to e.g. 2,4,6-trimethylbenzoyl, 2,6-dichlorobenzoyl, 2,6-dimethylbenzoyl or 2,6-dimethoxybenzoyl.

C₁-C₄Alkylene and C₂-C₆alkylene are linear or branched alkylene, for example C₂-C₄alkylene, e.g. methylene, ethylene, propylene, isopropylene, n-butylene, sec-butylene, isobutylene, tert-butylene, pentylene and hexylene. Preference is given to C₁-C₄alkylene, e.g. ethylene or butylene, 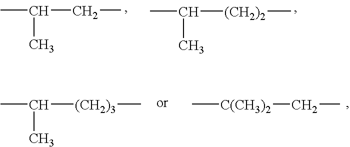
and also methylene and ethylene.

Phenylene-C₁-C₄alkylene is phenylene that is substituted by C₁-C₄alkylene in one position of the aromatic ring, while C₁-C₄alkylene-phenylene-C₁-C₄alkylene is phenylene that is substituted by C₁-C₄alkylene in two positions of the phenylene ring. The alkylene radicals are linear or branched and have, for example, the meanings given above up to the appropriate number of carbon atoms. Examples are

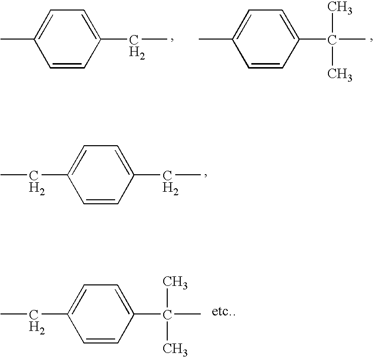

The alkylene groups may, however, also be positioned at other sites on the phenylene ring, e.g. also in the 1,3-position.

Cycloalkylene is e.g. C₃-C₁₂-, C₃-C₈-cycloalkylene, for example cyclopropylene, cyclopentylene, cyclohexylene, cyclooctylene, cyclododecylene, especially cyclopentylene and cyclohexylene, preferably cyclohexylene. C₃-C₁₂cycloalkylene also denotes, however, structural units such as 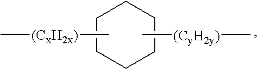
wherein x and y are each independently of the other from 0 to 6 and the sum of x+y≦6, or 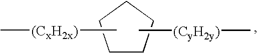
wherein x and y are each independently of the other from 0 to 7 and the sum of x+y≦7.

C₂-C₁₂Alkenyl radicals may be mono- or poly-unsaturated and linear or branched and are, for example, C₂-C₈-, C₂-C₆- or C₂-C₄-alkenyl. Examples are allyl, methallyl, 1,1-dimethylallyl, 1-butenyl, 2-butenyl, 1,3-pentadienyl, 1-hexenyl, 1-octenyl, decenyl and dodecenyl, especially allyl.

When R₇ and R₈ together are C₂-C₆alkylene, then together with the carbon atom to which they are bonded they form a C₃-C₇cycloalkyl ring. C₃-C₇cycloalkyl is, for example, cyclopropyl, cyclopentyl, cyclohexyl, cycloheptyl, especially cyclopentyl or cyclohexyl, preferably cyclohexyl.

R_{c}R_{b}C═CRₐ— is, for example, —CH═CH₂ or —C(CH₃)═CH₂, preferably —CH═CH₂.

After the application of the photoinitiator, the workpiece can be stored or immediately processed further, there being deposited a metal, half-metal or metal oxide from the gas phase.

In the context of the present invention electromagnetic radiation is used in steps c) and d). Prefereably this is UV/VIS radiation, which is to be understood as being electromagnetic radiation in a wavelength range from 150 nm to 700 nm. Preference is given to the range from 250 nm to 500 nm. Suitable lamps are known to the person skilled in the art and are commercially available.

A large number of the most varied kinds of light source may be used. Both point sources and planiform radiators (lamp arrays) are suitable. Examples are: carbon arc lamps, xenon arc lamps, medium-pressure, super-high-pressure, high-pressure and low-pressure mercury radiators doped, where appropriate, with metal halides (metal halide lamps), microwave-excited metal vapour lamps, excimer lamps, superactinic fluorescent tubes, fluorescent lamps, argon incandescent lamps, flash lamps, photographic floodlight lamps, light-emitting diodes (LED), electron beams and X-rays. The distance between the lamp and the substrate to be irradiated may vary according to the intended use and the type and strength of the lamp and may be, for example, from 2 cm to 150 cm. Also suitable are laser light sources, for example excimer lasers, such as Krypton-F lasers for irradiation at 248 nm. Lasers in the visible range may also be used.

The above description of suitable radiation sources relates both to irradiation step c) (fixing of the photoinitiator) in the process according to the invention and the procedure of process step d) (deposition of the metal, metal oxide or half-metal).

Advantageously the dose of radiation used in process step c) is e.g. from 1 to 1000 mJ/cm², such as 1-800 mJ/cm², or, for example, 1-500 mJ/cm², e.g. from 5 to 300 mJ/cm², preferably from 10 to 200 mJ/cm².

The process according to the invention can be carried out within a wide pressure range, the discharge characteristics shifting as the pressure increases from a pure low-temperature plasma towards a corona discharge and finally changing into a pure corona discharge at an atmospheric pressure of about 1000-1100 mbar.

The process is preferably carried out at a process pressure of from 10⁻⁶ mbar up to atmospheric pressure (1013 mbar), especially in the range of from 10⁻⁴ to 10⁻² mbar as a plasma process and at atmospheric pressure as a corona process. The flame treatment is usually carried out at atmospheric pressure.

The process is preferably carried out using as the plasma gas an inert gas or a mixture of an inert gas with a reactive gas.

When a corona discharge is used, air, CO₂ and/or nitrogen are preferably used as the gas. It is especially preferred to use air, H₂, CO₂, He, Ar, Kr, Xe, N₂, O₂ or H₂O singly or in the form of a mixture.

The photoinitiator layer deposited preferably has a thickness ranging from e.g. a monomolecular layer up to 500 nm, especially from 5 nm to 200 nm.

The plasma treatment of the inorganic or organic substrate a) preferably takes place for from 1 ms to 300 s, especially from 10 ms to 200 s.

In principle, it is advantageous to apply the photoinitiator as quickly as possible after the plasma-, corona- or flame-pretreatment, but for many purposes it may also be acceptable to carry out reaction step b) after a time delay. It is preferable, however, to carry out process step b) immediately after process step a) or within 24 hours after process step a). Of interest is a process wherein process step c) is carried out immediately after process step b) or within 24 hours after process step b).

The pretreated and photoinitiator-coated substrate can be subjected to process step d) immediately after the coating and drying in accordance with process steps a), b) and c) or it can be stored in the pretreated form.

The photoinitiator, or where applicable the mixture of a plurality of photoinitiators and/or coinitiators, is applied to the corona-, plasma- or flame-pretreated substrate, for example, in pure form, that is to say without further additives, or in combination with a monomer or oligomer, or dissolved in a solvent. The initiator, or the initiator mixture, can also e.g. be in molten form. The initiator, or the initiator mixture, can also, for example, be dispersed, suspended or emulsified in water, a dispersant being added as necessary. Of course, it is also possible to use any mixture of the above-mentioned components, photoinitiator, monomer, oligomer, solvent, water.

Suitable dispersants, e.g. any surface-active compounds, preferably anionic and non-ionic surfactants, and also polymeric dispersants, are usually known to the person skilled in the art and are described, for example, in U.S. Pat. No. 4,965,294 and U.S. Pat. No. 5,168,087.

Suitable solvents are in principle any substances in which the photoinitiator, or the photoinitiators, can be converted into a state suitable for application, whether in the form of a solution or in the form of a suspension or emulsion. Suitable solvents are, for example, alcohols, such as ethanol, propanol, isopropanol, butanol, ethylene glycol etc., ketones, such as acetone, methyl ethyl ketone, acetonitrile, aromatic hydrocarbons, such as toluene and xylene, esters and aldehydes, such as ethyl acetate, ethyl formate, aliphatic hydrocarbons, e.g. petroleum ether, pentane, hexane, cyclohexane, halogenated hydrocarbons, such as dichloromethane, choroform, or alternatively oils, natural oils, castor oil, vegetable oil etc., and also synthetic oils. This description is on no account exhaustive and is given merely by way of example.

Alcohols, water and esters are preferred.

The monomers and/or oligomers containing at least one ethylenically unsaturated group, which optionally are used in step b) of the process according to the invention may contain one or more ethylenically unsaturated double bonds. They may be lower molecular weight (monomeric) or higher molecular weight (oligomeric). Examples of monomers having a double bond are alkyl and hydroxyalkyl acrylates and methacrylates, e.g. methyl, ethyl, butyl, 2-ethylhexyl and 2-hydroxyethyl acrylate, isobornyl acrylate and methyl and ethyl methacrylate. Also of interest are silicone acrylates. Further examples are acrylonitrile, acrylamide, methacrylamide, N-substituted (meth)acrylamides, vinyl esters, such as vinyl acetate, vinyl ethers, such as isobutyl vinyl ether, styrene, alkyl- and halo-styrenes, N-vinylpyrrolidone, vinyl chloride and vinylidene chloride.

Examples of monomers having more than one double bond are ethylene glycol diacrylate, 1,6-hexanediol diacrylate, propylene glycol diacrylate, dipropylene glycol diacrylate, tripropylene glycol diacrylate, neopentyl glycol diacrylate, hexamethylene glycol diacrylate and bisphenol-A diacrylate, 4,4′-bis(2-acryloyloxyethoxy)diphenylpropane, trimethylolpropane triacrylate, pentaerythritol triacrylate, pentaerythritol tetraacrylate, vinyl acrylate, divinylbenzene, divinyl succinate, diallyl phthalate, triallyl phosphate, triallyl isocyanurate, tris-(hydroxyethyl) isocyanurate triacrylate (Sartomer 368; from Cray Valley) and tris(2-acryloyl-ethyl) isocyanurate.

It is also possible to use acrylic esters of alkoxylated polyols, for example glycerol ethoxylate triacrylate, glycerol propoxylate triacrylate, trimethylolpropaneethoxylate triacrylate, trimethylolpropanepropoxylate triacrylate, pentaerythritol ethoxylate tetraacrylate, pentaerythritol propoxylate triacrylate, pentaerythritol propoxylate tetraacrylate, neopentyl glycol ethoxylate diacrylate or neopentyl glycol propoxylate diacrylate. The degree of alkoxylation of the polyols used may vary.

Examples of higher molecular weight (oligomeric) polyunsaturated compounds are acrylated epoxy resins, acrylated or vinyl-ether- or epoxy-group-containing polyesters, polyurethanes and polyethers. Further examples of unsaturated oligomers are unsaturated polyester resins, which are usually produced from maleic acid, phthalic acid and one or more diols and have molecular weights of about from 500 to 3000. In addition it is also possible to use vinyl ether monomers and oligomers, and also maleate-terminated oligomers having polyester, polyurethane, polyether, polyvinyl ether and epoxide main chains. In particular, combinations of vinyl-ether-group-carrying oligomers and polymers, as described in WO 90/01512, are very suitable, but copolymers of monomers functionalised with maleic acid and vinyl ether also come into consideration.

Also suitable are, for example, esters of ethylenically unsaturated carboxylic acids and polyols or polyepoxides, and oligomers having ethylenically unsaturated groups in the chain or in side groups, e.g. unsaturated polyesters, polyamides and polyurethanes and copolymers thereof, alkyd resins, polybutadiene and butadiene copolymers, polyisoprene and isoprene copolymers, polymers and copolymers having (meth)acrylic groups in side chains, and also mixtures of one or more such polymers.

Examples of unsaturated carboxylic acids are acrylic acid, methacrylic acid, crotonic acid, itaconic acid, cinnamic acid and unsaturated fatty acids such as linolenic acid or oleic acid. Acrylic and methacrylic acid are preferred.

Suitable polyols are aromatic and especially aliphatic and cycloaliphatic polyols. Examples of aromatic polyols are hydroquinone, 4,4′-dihydroxydiphenyl, 2,2-di(4-hydroxyphenyl)propane, and novolaks and resols. Examples of polyepoxides are those based on the said polyols, especially the aromatic polyols and epichlorohydrin. Also suitable as polyols are polymers and copolymers that contain hydroxyl groups in the polymer chain or in side groups, e.g. polyvinyl alcohol and copolymers thereof or polymethacrylic acid hydroxyalkyl esters or copolymers thereof. Further suitable polyols are oligoesters having hydroxyl terminal groups.

Examples of aliphatic and cycloaliphatic polyols include alkylenediols having preferably from 2 to 12 carbon atoms, such as ethylene glycol, 1,2- or 1,3-propanediol, 1,2-, 1,3- or 1,4-butanediol, pentanediol, hexanediol, octanediol, dodecanediol, diethylene glycol, triethylene glycol, polyethylene glycols having molecular weights of preferably from 200 to 1500, 1,3-cyclopentanediol, 1,2-, 1,3- or 1,4-cyclohexanediol, 1,4-dihydroxymethylcyclohexane, glycerol, tris(β-hydroxyethyl)amine, trimethylolethane, trimethylolpropane, pentaerythritol, dipentaerythritol and sorbitol.

The polyols may have been partially or fully esterified by one or by different unsaturated carboxylic acid(s), it being possible for the free hydroxyl groups in partial esters to have been modified, for example etherified, or esterified by other carboxylic acids.

Examples of esters are:

trimethylolpropane triacrylate, trimethylolethane triacrylate, trimethylolpropane trimethacrylate, trimethylolethane trimethacrylate, tetramethylene glycol dimethacrylate, triethylene glycol dimethacrylate, tetraethylene glycol diacrylate, pentaerythritol diacrylate, pentaerythritol triacrylate, pentaerythritol tetraacrylate, dipentaerythritol diacrylate, dipentaerythritol triacrylate, dipentaerythritol tetraacrylate, dipentaerythritol pentaacrylate, dipentaerythritol hexaacrylate, tripentaerythritol octaacrylate, pentaerythritol dimethacrylate, pentaerythritol trimethacrylate, dipentaerythritol dimethacrylate, dipentaerythritol tetramethacrylate, tri-pentaerythritol octamethacrylate, pentaerythritol diitaconate, dipentaerythritol trisitaconate, dipentaerythritol pentaitaconate, dipentaerythritol hexaitaconate, ethylene glycol diacrylate, 1,3-butanediol diacrylate, 1,3-butanediol dimethacrylate, 1,4-butanediol diitaconate, sorbitol triacrylate, sorbitol tetraacrylate, pentaerythritol-modified triacrylate, sorbitol tetramethacrylate, sorbitol pentaacrylate, sorbitol hexaacrylate, oligoester acrylates and methacrylates, glycerol di- and tri-acrylate, 1,4-cyclohexane diacrylate, bisacrylates and bismethacrylates of polyethylene glycol having a molecular weight of from 200 to 1500, and mixtures thereof.

Also suitable are the amides of identical or different unsaturated carboxylic acids and aromatic, cycloaliphatic and aliphatic polyamines having preferably from 2 to 6, especially from 2 to 4, amino groups. Examples of such polyamines are ethylenediamine, 1,2- or 1,3-propylenediamine, 1,2-, 1,3- or 1,4-butylenediamine, 1,5-pentylenediamine, 1,6-hexylenediamine, octylenediamine, dodecylenediamine, 1,4-diamino-cydohexane, isophoronediamine, phenylenediamine, bisphenylenediamine, di-β-aminoethyl ether, diethylenetriamine, triethylenetetramine and di(β-aminoethoxy)- and di(β-aminopropoxy)ethane. Further suitable polyamines are polymers and copolymers which may have additional amino groups in the side chain and oligoamides having amino terminal groups. Examples of such unsaturated amides are: methylene bisacrylamide, 1,6-hexamethylene bisacrylamide, diethylenetriamine trismethacrylamide, bis(methacrylamidopropoxy)ethane, β-methacrylamidoethyl methacrylate and N-[(β-hydroxyethoxy)ethyl]-acrylamide.

Suitable unsaturated polyesters and polyamides are derived, for example, from maleic acid and diols or diamines. The maleic acid may have been partially replaced by other dicarboxylic acids. They may be used together with ethylenically unsaturated comonomers, e.g. styrene. The polyesters and polyamides may also be derived from dicarboxylic acids and ethylenically unsaturated diols or diamines, especially from those having longer chains of e.g. from 6 to 20 carbon atoms. Examples of polyurethanes are those composed of saturated diisocyanates and unsaturated diols or unsaturated diisocyanates and saturated diols.

Polybutadiene and polyisoprene and copolymers thereof are known. Suitable comonomers include, for example, olefins, such as ethylene, propene, butene, hexene, (meth)acrylates, acrylonitrile, styrene and vinyl chloride. Polymers having (meth)acrylate groups in the side chain are likewise known. Examples are reaction products of novolak-based epoxy resins with (meth)acrylic acid; homo- or co-polymers of vinyl alcohol or hydroxyalkyl derivatives thereof that have been esterified with (meth)acrylic acid; and homo- and co-polymers of (meth)acrylates that have been esterified with hydroxyalkyl (meth)acrylates.

In the context of the present Application the term (meth)acrylate includes both the acrylate and the methacrylate.

An acrylate or methacrylate compound is especially used as the mono- or poly-ethylenically unsaturated compound.

Very special preference is given to polyunsaturated acrylate compounds, such as have already been mentioned above.

The invention therefore relates also to a process wherein the photoinitiators or mixtures thereof with monomers or oligomers are used in combination with one or more liquids (such as solvents or water) in the form of solutions, suspensions and emulsions.

Also of interest is a process wherein the photoinitiator used in process step b) or the mixture of photoinitiators is used in molten form.

After the plasma-, corona- or flame-pretreatment, it is therefore possible in process step b) to apply to the pretreated substrate, for example, 0.1-15%, e.g. 0.1-5%, of a photoinitiator having an unsaturated group or, for example, 0.1-15%, e.g. 0.1-5%, of a photoinitiator, e.g. one without an unsaturated group, and e.g. 0.5-10% of a monomer, such as an acrylate, methacrylate, vinyl ether etc..

The application of the photoinitiators, or mixtures thereof with one another or with monomers or oligomers, in the form of melts, solutions, dispersions, suspensions or emulsions, can be carried out in various ways. Application can be effected by immersion, spraying, coating, brush application, knife application, roller application, printing, spin-coating and pouring. In the case of mixtures of photoinitiators with one another and with coinitiators and sensitisers, all possible mixing ratios can be used. When only one photoinitiator or photoinitiator mixture is to be applied to the pretreated substrate, the concentration of those initiators is, of course, 100%.

When the photoinitiators are applied in the form of mixtures with monomers or/and solvents or/and water in the form of liquids, solutions, emulsions or suspensions, they are used, for example, in concentrations of from 0.01 to 99.9%, or 0.01-80%, e.g. 0.1-50%, or 10-90%, based on the solution being applied. The liquids comprising the photoinitiator may, in addition, contain e.g. further substances, such as defoamers, emulsifiers, surfactants, anti-fouling agents, wetting agents and other additives customarily used in the industry, especially the coating and paint industries.

Many possible methods of drying coatings are known and they can all be used in the claimed process. For example, it is possible to use hot gases, IR radiators, microwaves and radio frequency radiators, ovens and heated rollers. Drying can also be effected, for example, by absorption, e.g. penetration into the substrate. This relates especially to the drying in process step c), but applies also to the drying carried out in process step d2). Drying can take place, for example, at temperatures of from 0° C. to 300° C., for example from 20° C. to 200° C. The irradiation of the coating in order to fix the photoinitiator in process step c) (and also to cure the formulation in process step d1) can be carried out, as already mentioned above, using any sources that emit electromagnetic waves of wavelengths that can be absorbed by the photoinitiators used. Such sources are generally light sources that emit light in the range from 200 nm to 700 nm. It may also be possible to use electron beams. In addition to customary radiators and lamps it is also possible to use lasers and LEDs (Light Emitting Diodes). The whole area of the coating or parts thereof may be irradiated. Partial irradiation is of advantage when only certain regions are to be rendered adherent. Irradiation can also be carried out using electron beams.

The drying and/or irradiation can be carried out under air or under inert gas. Nitrogen gas comes into consideration as inert gas, but other inert gases, such as CO₂ or argon, helium etc. or mixtures thereof, can also be used. Suitable systems and apparatus are known to the person skilled in the art and are commercially available.

Examples for metals, half-metals and metal oxides to be deposited on the pre-treated substrate after the pre-treatment are the following: zinc, copper, nickel, gold, silver, platiunum, palladium, chromium, molybdenum, aluminum, iron, titanium. Preferred are gold, silver, chromium, molybdenum, aluminum or copper, especially aluminum and copper. Interesting further are the following half-metals and metal oxides: aluminum oxide, chromium oxide, iron oxide, copper oxide and silicon oxide. Preferred are gold, Silver, chromium, molybdenum, aluminum or copper.

The metals, half-metals or metal oxides are evaporated under vacuum conditions and deposited onto the substrate which is pretreated with the photoinitiator layer. This deposition may take place while irradiating with electromagnetic radiation. On the other hand, it is possible to carry out the irradiation after the deposition of the metal. The pot-temperatures for the deposition step depend on the metal which is used and preferably are for example in the range from 300 to 2000° C., in particular in the range from 800 to 1800° C.

The UV radiation during the deposition step can for example be produced by an anodic light arc, while for the UV radiation after the deposition the usual lamps as described above are also suitable.

The substrates coated with the metals are for example suitable as diffusion inhibiting layers, for electromagnetic shields or they can be used as decoratove elements, for decorative foils, or for foils used for packaging, for example, for food packaging.

The invention relates also to the use of photoinitiators and photoinitiator systems in the process according to the invention.

The invention relates also to strongly adherent metal coatings obtainable in accordance with the process described above.

Such strongly adherent coatings are important not only as protective layers or coverings, which may additionally be pigmented, but also for image-forming coatings, for example in resist and printing plate technology. In the case of image-forming processes, the irradiation can be effected through a mask or by writing using moving laser beams (Laser Direct Imaging—LDI). Such partial irradiation can be followed by a development or washing step in which portions of the applied coating are removed by means of solvents and/or water or mechanically.

When the process according to the invention is used in the production of image-forming coatings (imaging), the image-forming step can be carried out in process step c).

The invention therefore relates also to a process wherein portions of the photoinitiators, or mixtures thereof with monomers and/or oligomers, applied in process step b) that have not been crosslinked after irradiation in process step c) are removed by treatment with a solvent and/or water and/or mechanically.

The following Examples further illustrate the invention but it is not intended to limit the invention to the Examples. Here, as in the remainder of the description and in the claims, parts and percentages relate to weight, unless otherwise indicated.

### EXAMPLE 1

The plasma treatment is carried out in a plasma reactor at 13.56 MHz and a variable output of from 10 to 100 W. A polyethylene foil (PE foil) is exposed to an argon/oxygen plasma (gas flows: argon 10 sccm, oxygen 2.5 sccm) at an output of 20 W for 1 second at room temperature and a pressure of 5 Pa. Air is then admitted and the sample is coated with a formulation S1, comprising

1% of the photoinitiator P38, a copolyermizable benzophenone, provided by UCB;

0,2% of bis(2,4,6-trimethylbenzoyl)-phenyl-phosphine oxide, Irgacure 819, provided by Ciba Specialty Chemicals, Switzerland;

1% of tris(hydroxyethyl)-isocyanurat-triacrylate, Sartomer 368, provided by Cray Valley and iso-propanol, by using a 4 μm bar.

After drying, the sample is irradiated with a 80W/cm mercury lamp, at a belt speed of 50m/min.

After coating with the photoinitiator layer in the same reactor a copper-layer is deposited in an anodic light arc process (VALICO process), at a pressure of 2·10⁻⁴ mbar. The pot temperature is 1500-1600° C. In about one minute a layer of 1 μm thickness is deposited. The adhesive strength is determined by tearing off an adhesive tape. The copper layer is not removed by the tape.

### EXAMPLE 2

The procedure is as described in Example 1, only instead of the PE foil a biaxial oriented polypropylene (BOPP) foil is used. In the test with the adhesive tape, the copper layer is not removed.

### EXAMPLE 3

The procedure is as described in Example 1, only instead of the formulation S1 the following formulation S2, comprising

1% of the photoinitiator P38, a copolyermizable benzophenone, provided by UCB;

0,2% of bis(2,4,6-trimethylbenzoyl)-phenyl-phosphine oxide, Irgacure 819, provided by Ciba Specialty Chemicals, Switzerland;

1% of an aromatic acid methacrylate halfester (Sarbox 400, provided by Sartomer) iso-propanol; is used. Again, in the test the copper layer is not removed by the tape.

### EXAMPLE 4

The procedure is as described in Example 1, only instead of the formulation S1 the formulation S2, is used and as the substrate the PE foil is replaced by a BOPP foil. The tape test shows that the copper layer is well adhering on the substrate.

### EXAMPLE 5

A polyethylene foil (PE foil) is Corona-treated (600W 5 m/min). On said corona-treated substrate a formulation S1 is applied and irradiated. The sample is transferred to the reactor as used in example 1 and a copper-layer is deposited in an anodic light arc process (VALICO process), at a pressure of 2·10⁻⁴ mbar. The pot temperature is 1500-1600° C. In about one minute a layer of 1 μm thickness is deposited. In the test, the copper layer is not removed by the adhesive tape.

### EXAMPLE 6

The procedure is as described in Example 5, only the PE foil is exchanged by a BOPP foil. The result of the test demonstrates a good adherance of the deposited copper layer on the substrate.

### EXAMPLE 7

The procedure is as described in Example 5, only the formulation S1 is exchanged by the formulation S2. The copper layer shows a good adherance on the substrate.

### EXAMPLE 8

The procedure is as described in Example 5, only the PE foil is exchanged by a BOPP foil and the formulation S1 is exchanged by the formulation S2. The result of the test demonstrates a good adherance of the deposited copper layer on the substrate.

1. A process for the production of a strongly adherent metal coating on an inorganic or organic substrate, wherein
a) a low temperature plasma treatment, a corona discharge treatment or a flame treatment is carried out on the inorganic or organic substrate,
b) one or more photoinitiators or mixtures of photoinitiators with monomers or/and oligomers, containing at least one ethylenically unsaturated group, or solutions, suspensions or emulsions of the afore-mentioned substances, are applied to the inorganic or organic substrate,
c) the layer of step b) is optionally dried and is irradiated with electromagnetic waves; and
d) on the substrate so precoated with photoinitiator a metal, half-metal or metal oxide is deposited from the gasphase.

2. A process according to claim 1, wherein step d) an irradiation with electromagnetic waves is carried out, either while depositing the metal, half-metal or metal oxide from the gasphase or after the deposition.

3. A process according to claim 1, wherein the photoinitiator is a compound or combination of compounds from the classes of benzoins, benzil ketals, acetophenones, hydroxyalkylphenones, aminoalkylphenones, acylphosphine oxides, acylphosphine sulfides, acyloxyiminoketones, peroxy compounds, halogenated acetophenones, phenylglyoxylates, dimeric phenylglyoxalates, benzophenones, oximes and oxime esters, thioxanthones, thiazolines, ferrocenes, coumarins, dinitrile compounds, titanocenes, sulfonium salts, iodonium salts, diazonium salts, onium salts, borates, triazines, bisimidazoles, polysilanes and dyes, and also corresponding coinitiators and/or sensitisers.

4. A process according to claim 1, wherein the photoinitiator is a compound of formula I or Ia
(RG)—A—(IN) (I),
(IN)—A—(RG′)—A—(IN) (Ia),
wherein
(IN) is a photoinitiator base structure;
A is a spacer group or a single bond;
(RG) is hydrogen or at least one functional ethylenically unsaturated group; and
(RG′) is a single bond or a divalent radical that contains at least one functional ethylenically unsaturated group, or is a trivalent radical.

5. A process according to claim 4, wherein in the compound of formula I or Ia (IN) is a photoinitiator base structure of formula (II) or (III) 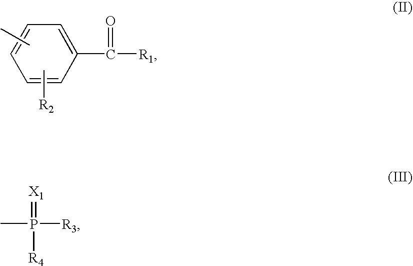
R₁ is a group (A), (B), (C) or (III) 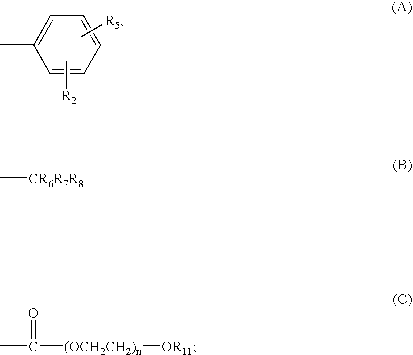
n is a number from 0 to 6;
R₂ is hydrogen, C₁-C₁₂alkyl, halogen, the group (RG)—A— or, when R₁ is a group (A), two radicals
R₂ in the ortho-position to the carbonyl group may also together be —S— or 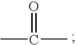
R₃ and R₄ are each independently of the other C₁-C₆alkyl, C₁-C₆alkanoyl, phenyl or benzoyl, the radicals phenyl and benzoyl each being unsubstituted or substituted by halogen, C₁-C₆alkyl, C₁-C₆alkylthio or by C₁-C₆alkoxy;
R₅ is hydrogen, halogen, C₁-C₁₂alkyl or C₁-C₁₂alkoxy or the group (RG)—A—;
R₆ is OR₉ or N(R₉)₂ or 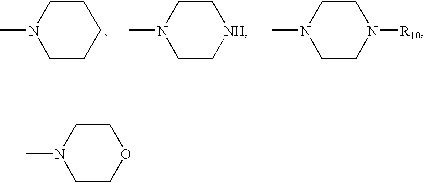
or SO₂R₉;
R₇ and R₈ are each independently of the other hydrogen, C₁-C₁₂alkyl, C₂-C₁₂alkenyl, C₁-C₁₂alkoxy, phenyl or benzyl or R₇ and R₈ together are C₂-C₆alkylene;
R₉ is hydrogen, C₁-C₆alkyl or C₁-C₆alkanoyl;
R₁₀ is hydrogen, C₁-C₁₂alkyl or phenyl;
R₁₁ is C₁-C₄alkyl or 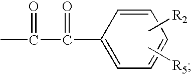
and
X₁ is oxygen or sulfur.

6. A process according to claim 5, wherein in the compound of formula I or Ia
(RG) is R_{c}R_{b}C═CRₐ—;
(RG′) is 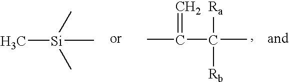
and
Rₐ, R_{b} and R_{c} are each independently of the other hydrogen or C₁-C₆alkyl.

7. A process according to claim 1, wherein the photoinitiator(s) or mixtures thereof with monomers or oligomers are used in combination with one or more liquids in the form of solutions, suspensions and emulsions.

8. A process according to claim 1, wherein an inert gas or a mixture of inert gas with reactive gas is used as the plasma gas.

9. A process according to claim 8, wherein air, H₂, CO₂, He, Ar, Kr, Xe, N₂, O₂ or H₂) are used singly or in the form of a mixture.

10. A process according to claim 1, wherein the photoinitiator layer applied has a layer thickness of up to 500 nm.

11. A process according to claim 1, wherein process step b) is carried out immediately after process step a) or within 24 hours after process step a).

12. A process according to claim 1, wherein the concentration of photoinitiator or photoinitiators in process step b) is from 0.01 to 99.5%.

13. A process according to claim 1, wherein process step c) is carried out immediately after process step b) or within 24 hours after process step b).

14. A process according to claim 1, wherein drying in process step c) is effected in ovens, with hot gases, heated rollers or IR or microwave radiators or by absorption.

15. A process according to claim 1, wherein irradiation in process step c) and/or d) is effected with a source that emits electromagnetic waves of wavelengths in the range from 200 nm to 700 nm, or by electron beams.

16. A process according to claim 1, wherein portions of the photoinitiators, or mixtures thereof with monomers and/or oligomers, applied in process step b) that have not been crosslinked after irradiation in process step c) are removed by treatment with a solvent and/or water and/or mechanically.

17. A process according to claim 1, wherein after irradiation in process step d) portions of the coating are removed by treatment with a solvent and/or water and/or mechanically.

18. (canceled)

19. A strongly adherent coating obtained by a process according to claim 1.

20. A strongly adherent coating obtained by a process according to claim 2.

21. A process according to claim 2, wherein an inert gas or a mixture of inert gas with reactive gas is used as the plasma gas.
